(19) United States
(12) Patent Application Publication
(10) Pub. No.: US 2019/0363020 A1
(43) Pub. Date: Nov. 28, 2019

(54) DIE SINGULATION SYSTEMS AND METHODS

(71) Applicant: SEMICONDUCTOR COMPONENTS INDUSTRIES, LLC, Phoenix, AZ (US)

(72) Inventor: Michael J. SEDDON, Gilbert, AZ (US)

(73) Assignee: SEMICONDUCTOR COMPONENTS INDUSTRIES, LLC, Phoenix, AZ (US)

(21) Appl. No.: 15/988,262

(22) Filed: May 24, 2018

(51) Int. Cl. H01L 21/82; H01L 21/683; B23K 26/53; B23K 26/00; B23K 26/08

(52) U.S. Cl. CPC H01L 21/8213; H01L 21/6836; B23K 26/53; B23K 2201/40; B23K 26/0057; B23K 26/0853; B23K 26/0006

(57) ABSTRACT

Implementations of a method of singulating a plurality of die from a semiconductor substrate may include: forming a damage layer beneath a surface of a die street where the die street connects a plurality of semiconductor die formed on a semiconductor substrate. The method may include mounting the semiconductor substrate to a support tape, exposing the semiconductor substrate to sonic energy using a sonic energy source, and singulating the plurality of die at the damage layer using the sonic energy.

### BACKGROUND

### Technical Field

Aspects of this document relate generally to systems and methods for singulating die from semiconductor substrates.

### 2. BACKGROUND

Semiconductor devices are typically formed on and into the surface of a semiconductor substrate. As the semiconductor substrate is typically much larger than the devices, the devices are singulated one from another into various semiconductor die. Sawing the semiconductor substrate is a method used to separate the semiconductor die from each other.

### SUMMARY

Implementations of a method of singulating a plurality of die from a semiconductor substrate may include: forming a damage layer beneath a surface of a die street where the die street connects a plurality of semiconductor die formed on a semiconductor substrate. The method may include mounting the semiconductor substrate to a support tape, exposing the semiconductor substrate to sonic energy using a sonic energy source, and singulating the plurality of die at the damage layer using the sonic energy.

Implementations of a method of singulating a plurality of die may include one, all, or any of the following:

The sonic energy source may emit sonic energy between 20 kHz to 3 GHz.

Forming a damage layer may further include irradiating the die street with a laser beam at a focal point within the semiconductor substrate at one or more spaced apart locations beneath the surface of the die street to form the damage layer.

Forming a damage layer may further include irradiating the die street with a laser beam at a focal point at a first depth within the semiconductor substrate at one or more spaced apart locations beneath the surface of the die street and irradiating the die street with a laser beam at a focal point at a second depth within the semiconductor substrate at one or more spaced apart locations beneath the surface of the die street.

The semiconductor substrate may be silicon carbide.

Singulating the plurality of die at the damage layer may further include stretching the support tape while applying the sonic energy.

Singulating the plurality of die at the damage layer may further include applying a continuous or semicontinuous bias force across a surface of the semiconductor substrate while applying the sonic energy.

Singulating the plurality of die at the damage layer may further include applying a moving localized bias force across a surface of the semiconductor substrate while applying the sonic energy.

Singulating the plurality of die at the damage layer may further include applying a plurality of point bias forces distributed across a surface of the semiconductor substrate while applying the sonic energy.

Implementations of a method of singulating a plurality of die from a semiconductor substrate may include irradiating the die street with a laser beam at a focal point within the semiconductor substrate at one or more spaced apart locations beneath the surface of the die street to form a damage layer beneath a surface of a die street where the die street connects a plurality of semiconductor die formed on the semiconductor substrate. The method may also include mounting the semiconductor substrate to a support tape, exposing the semiconductor substrate to sonic energy using a sonic energy source, and singulating the plurality of die at the damage layer using the sonic energy.

Implementations of a method of singulating a plurality of die from a semiconductor substrate may include one, all, or any of the following:

The sonic energy source may emit sonic energy between 20 kHz to 3 GHz.

Irradiating the die street with the laser beam may further include irradiating the die street with the laser beam at the focal point at a first depth within the semiconductor substrate at the one or more spaced apart locations beneath the surface of the die street and irradiating the die street with the laser beam at a focal point at a second depth within the semiconductor substrate at one or more spaced apart locations beneath the surface of the die street.

The semiconductor substrate may be silicon carbide.

Singulating the plurality of die at the damage layer may further include stretching the support tape while applying the sonic energy.

Singulating the plurality of die at the damage layer may further include applying a continuous or semicontinuous bias force across a surface of the semiconductor substrate while applying the sonic energy.

Singulating the plurality of die at the damage layer may further include applying a moving localized bias force across a surface of the semiconductor substrate while applying the sonic energy.

Singulating the plurality of die at the damage layer may further include applying a plurality of point bias forces distributed across a surface of the semiconductor substrate while applying the sonic energy.

Implementations of a method singulating a plurality of die from a silicon carbide substrate may include irradiating the die street with a laser beam at a focal point within the silicon carbide substrate at one or more spaced apart locations beneath the surface of the die street to form a damage layer beneath a surface of a die street where the die street connects a plurality of semiconductor die formed on the silicon carbide semiconductor substrate. The method may include mounting the silicon carbide substrate to a support tape and singulating the plurality of die at the damage layer using sonic energy from a sonic energy source.

Implementations of a method of singulating a plurality of die from a silicon carbide substrate may include one, all, or any of the following:

Singulating the plurality of die at the damage layer may further include stretching the support tape while applying the sonic energy.

Singulating the plurality of die at the damage layer may further include applying a continuous or semicontinuous bias force across a surface of the semiconductor substrate while applying the sonic energy.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of a semiconductor substrate during laser irradiation showing a plurality of streets;

FIG. 2 is a cross sectional view of a semiconductor substrate mounted to a frame through support tape during laser irradiation showing a plurality of streets;

FIG. 3 is a cross sectional view of a semiconductor substrate mounted to support tape immersed in a bath experiencing sonic energy from a sonic energy source;

FIG. 4 is a cross sectional view of a semiconductor substrate mounted to support tape with liquid covering the upper surface of the substrate experiencing sonic energy from a support holding the semiconductor substrate;

FIG. 5 is a cross sectional view of a semiconductor substrate following laser irradiation during stretching of the support tape;

FIG. 6 is a cross sectional view of a semiconductor substrate following laser irradiation during application of a plurality of point bias forces at points across a bottom surface of the semiconductor surface using a plurality of points connected to a lifting mechanism;

FIG. 7 is a cross sectional view of a semiconductor substrate following laser irradiation during application of a continuous bias force across a bottom surface of the semiconductor surface using a lifting mechanism and contoured chuck;

FIG. 8 is a cross sectional view of a semiconductor substrate following laser irradiation during application of a moving localized bias force across a surface of the semiconductor substrate using a roller.

### DESCRIPTION

This disclosure, its aspects and implementations, are not limited to the specific components, assembly procedures or method elements disclosed herein. Many additional components, assembly procedures and/or method elements known in the art consistent with the intended die singulation systems and methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such die singulation systems and methods, and implementing components and methods, consistent with the intended operation and methods.

A wide variety of semiconductor substrate types exist and are used in the process of manufacturing various semiconductor devices. Non-limiting examples of semiconductor substrates that may be processed using the principles disclosed in this document include single crystal silicon, silicon dioxide, glass, silicon-on-insulator, gallium arsenide, sapphire, ruby, silicon carbide, polycrystalline or amorphous forms of any of the foregoing, and any other substrate type useful for constructing semiconductor devices. Particular implementations disclosed herein may utilize silicon carbide semiconductor substrates (silicon carbide substrates) of any polytype. In this document the term “wafer” is also used along with “substrate” as a wafer is a common type of substrate, but not as an exclusive term that is used to refer to all semiconductor substrate types. The various semiconductor substrate types disclosed in this document may be, by non-limiting example, round, rounded, square, rectangular, or any other closed shape in various implementations.

Referring to FIG. 1, a semiconductor substrate 2 with a plurality of streets (die streets) 4 is illustrated. As illustrated, the street 4 is the area of the semiconductor substrate between die areas 6, 8 and extends across the thickness of the semiconductor substrate 2. Since this is a cross sectional view, multiple die areas 6, 8 are visible in this view, and the street extends across a plurality of die spaced apart across the surface of the semiconductor substrate 2. In this implementation, a laser beam 10 is irradiating the material of the street 4 at a focal point 14 beneath a surface 18 of the street 4. Because the laser beam 10 causes localized heating at the focal point 14, the structure of the material at the focal point is disrupted. The semiconductor substrate 2 illustrated in FIG. 1 is a single crystal silicon carbide substrate.

The degree of damage done at the focal point is determined by many factors, including, by non-limiting example, the power of the laser light, the duration of exposure of the material, the absorption of the material of the substrate, the crystallographic orientation of the substrate material relative to the direction of the laser light, the atomic structure of the substrate, and any other factor regulating the absorbance of the light energy and/or transmission of the induced damage or heat into the substrate. The wavelength of the laser light used to irradiate the street 4 is one for which the material of the particular semiconductor substrate is at least partially optically transmissive, whether translucent or transparent. Where the substrate is a silicon carbide substrate, the wavelength may be 1064 nm. In various implementations, the laser light source may be a Nd:YAG pulsed laser or a YVO4 pulsed laser. In one implementation where a Nd:YAG laser is used, a spot size of 10 microns and an average power of 3.2 W may be used along with a repetition frequency of 80 kHz, pulse width of 4 ns, numerical aperture (NA) of the focusing lens of 0.45. In another implementation, a Nd:YAG laser may be used with a repetition frequency of 400 kHz, average power of 16 W, pulse width of 4 ns, spot diameter of 10 microns, and NA of 0.45. In various implementations, the power of the laser may be varied from about 2 W to about 4.5 W. In other implementations, however, the laser power may be less than 2 W or greater than 4.5 W.

As illustrated, the focal point 14 of the laser light forms a location of rapid heating and may result in full or partial melting of the material at the focal point 14. The point of rapid heating and the resulting stress on the hexagonal single crystal structure of the SiC substrate as a result of the heating/cooling results in cracking of the substrate material along a c-plane of the substrate. Depending on the type of single SiC crystal used to manufacture the boule, the c-plane may be oriented at an off angle to the second surface of about 1 degree to about 6 degrees. In various implementations, this angle is determined at the time the boule is manufactured. In particular implementations, the off angle may be about 4 degrees.

During operation, the laser is operated in pulsed operation to create numerous overlapping spots of pulsed light while passing across the surface of the substrate. As a result, a continuous/semi-continuous layer/band of modified material is formed within the wafer. In other implementations, the laser may be operated in continuous wave mode rather than pulsed mode to create the band of modified material. As illustrated, the stress caused by the focal point 14 causes cracking along the c-plane in the material of the street 4 in one or both directions along the c-plane. These cracks 16 are illustrated as spreading from the focal point 14 area (where the modified layer/band is located) angled at the off angle in FIG. 1. In various implementations, the cracks 16 may be located below the focal point 14, above the focal point 14, or spread directly from the focal point 14, depending on the characteristics of the laser and the method of application of the laser to the material. In various implementations, the length of the cracks 16 into the substrate is a function of the power of the laser applied. By non-limiting example, the depth of the focal point was set at 500 um into the substrate; where the laser power was 3.2 W, the crack propagation from the modified layer/band was about 250 um; where the laser power was at 2 W, the crack lengths were about 100 um; where the laser power was set at 4.5 W, the crack lengths were about 350 um.

As illustrated in FIG. 1, the laser beam 10 is in the process of making a fourth pass along the street at a fourth depth into the substrate from the three previously made passes. In various implementations, one, two, or more passes may be conducted in any street at any desired depth and two or more passes at different spaced apart locations in the street may also be conducted at two or more depths into the material of the street (below the surface of the street) in various implementations. The various passes may use the same laser parameters and feed speeds/rates or may be conducted using different laser parameters and different feed speeds/rates. The disrupted material and cracks from the laser irradiation form a damage layer beneath the surface 18 of the street 4. The damage layer breaks up the structure of the semiconductor substrate material (in the case of SiC, the hexagonal crystalline structure of the substrate) thereby weakening the strength of the material. As illustrated in FIG. 1, the process of laser irradiation has taken place on the other street regions 4 in the substrate 2. In the implementation illustrated in FIG. 1, the laser irradiation has taken place through handling the substrate 2 itself. In various implementations, the laser irradiation may be carried out from the device side or the side of the substrate opposing the device side (back side) of the substrate depending on the desired processing parameters and whether the back side or device side of the wafer has any materials on it that would prevent the laser light from entering the street region (back side metal, etc.). In FIG. 1 a device side is not explicitly shown to indicate that the laser irradiation can be conducted from either side of the substrate. In implementations where laser irradiation is done from the back side of the substrate, the use of front (device) side alignment cameras on the laser device may be used to align the wafer to ensure laser irradiation takes place in the desired regions.

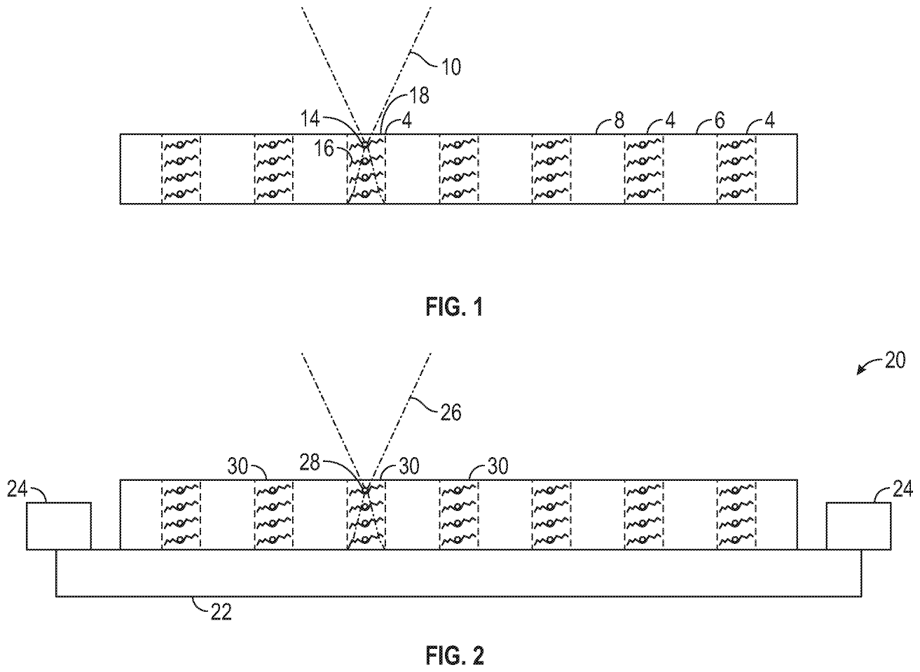

Referring to FIG. 2, a semiconductor substrate 20 is illustrated mounted on support tape 22 coupled to frame 24. As illustrated, this substrate 20 is also being irradiated using laser beam 26 at a focal point 28 below the surface of street region 30 at a fourth depth into the street region. The other street regions have been similarly irradiated as those illustrated in FIG. 1 using a single pass, multidepth process. FIG. 2 illustrates how, in various implementations, the laser irradiation process can be conducted after the substrate is mounted on wafer support tape. In such implementations, the irradiation may generally be done with the front (device) side of the substrate facing the laser to reduce difficulty from trying to use front side cameras that can see alignment features through the support tape, though in some implementations, irradiation with the back side of the substrate may be utilized.

A wide variety of support tape types could be used in various method implementations including, by non-limiting example, sawing tapes, die attach film (DAF) tapes, ultraviolet tapes, stretching tapes, and any other flexible material capable of supporting a plurality of die during and after the singulation process. Various mounting equipment may be employed to mount the substrates prior to laser irradiation as illustrated in FIG. 2, or after substrate laser irradiation as illustrated in FIG. 1.

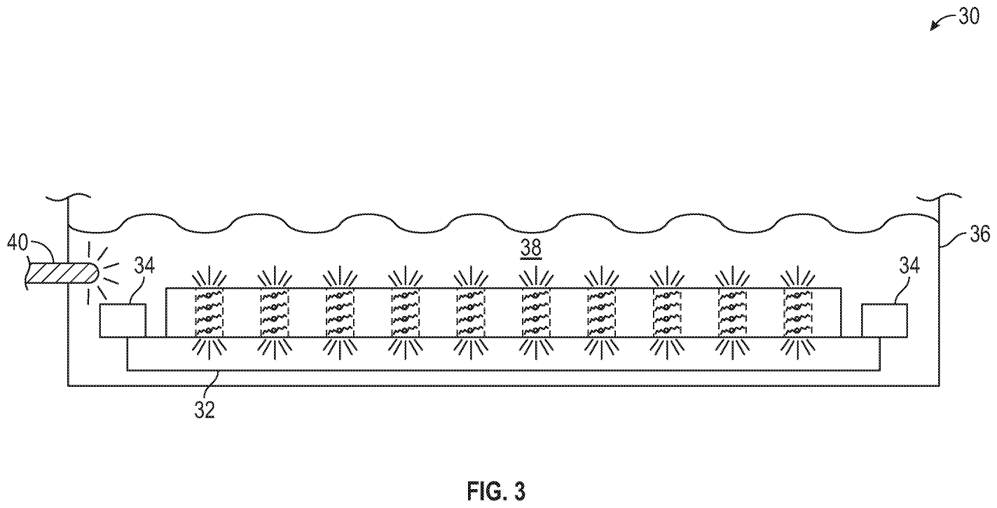

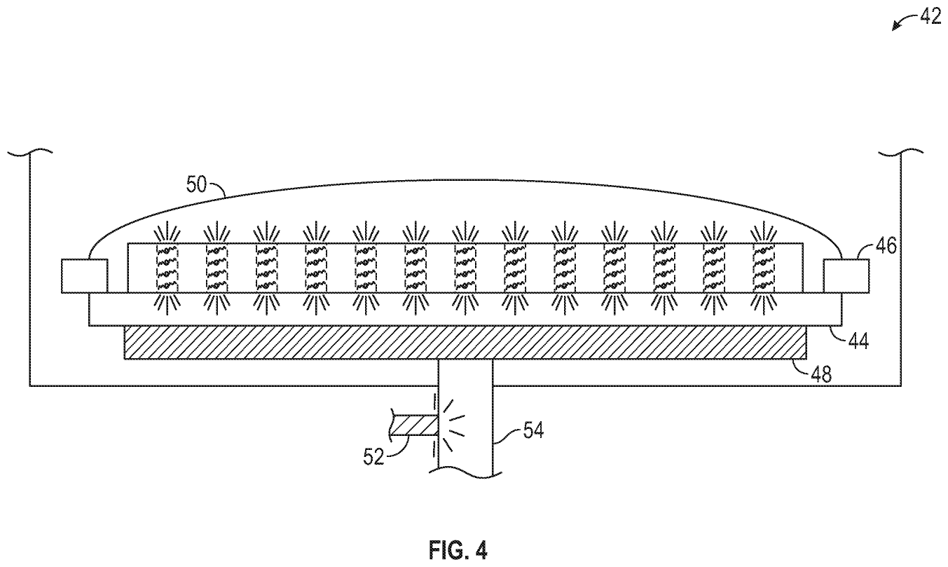

Referring to FIG. 3, a semiconductor substrate 30 mounted to support tape 32 and frame 34 is illustrated immersed in bath 36. Bath 36 is illustrated filled with liquid 38 in contact with sonic energy source 40. A wide variety of liquids could be employed to be in static or flowing contact with the various components of the system, such as, by non-limiting example, aqueous liquids, organic liquids, water, solvents, and any other liquid that exists as a liquid under the conditions within the bath 36. The substrate 30 may be supported in the bath 36 by any of a wide variety of mechanisms, including, by non-limiting example, a chuck, a vacuum chuck, pins, clamps, or any other device designed to hold the frame in place in the bath. Referring to FIG. 4, another substrate 42 coupled to support tape 44 and frame 46 is illustrated coupled with chuck 48 where the substrate 42 is covered with liquid 50 that forms a pool over the upper surface of the substrate (whether back side or device side) opposing the tape 44. In the implementation illustrated in FIG. 4, a sonic energy source 52 is coupled with the spindle/support 54 of the chuck 48 and transfers sonic energy to the substrate 42 thereby. In some implementations, however, the sonic energy source may be coupled to the chuck 48 directly or be embedded in the chuck. While in the implementation illustrated in FIG. 4 the liquid 50 is puddled over the substrate, in other implementations, the liquid 50 may not be puddled and the substrate and chuck may be immersed in a bath similar to FIG. 3.

As illustrated in FIGS. 3 and 4, the sonic energy from the sonic energy sources 40, 52 acts on the damage layers formed in the street regions of the substrates causing cracks to propagate through the damage layers. In various implementations, as illustrated in FIGS. 3 and 4, the sonic energy is sufficient to cause the plurality of die in the substrate to singulate entirely from one another through propagation of the cracks through the thickness of the substrate in all of the laser damage street regions. At this point, the plurality of die are then supported entirely through the support tape 32, 48 and the corresponding frames 34, 44. The frames 34, 44 can then be removed from the bath 36 or the chuck 48 and then the plurality of die can be picked/removed for use in subsequent packaging operations.

In various implementations, the form of the sonic energy source may include a probe that extends into the wafer and which is vibrationally isolated from the vessel into which the probe extends so that the sonic energy generated by the probe substantially transmits into the water medium and not into the material of the vessel itself (like sonic energy source 40). Multiple sonic energy sources may be coupled to the liquid medium in various implementations. The sonic energy source may employ a wide variety of transducer designs in various implementations, including, by non-limiting example, magnetostrictive transducers and piezoelectric transducers. In the case where a magnetostrictive transducer is utilized, the transducer utilizes a coiled wire to form an alternating magnetic field inducing mechanical vibrations at a desired frequency in a material that exhibits magnetostrictive properties, such as, by non-limiting example, nickel, cobalt, terbium, dysprosium, iron, silicon, bismuth, aluminum, oxygen, any alloy thereof, and any combination thereof. The mechanical vibrations are then transferred to the portion of the sonic energy source that contacts the liquid (or spindle or other component of the system). Where a piezoelectric transducer is employed, a piezoelectric material is subjected to application of electric charge and the resulting vibrations are transferred to the portion of the sonic energy source that contacts the liquid. Example of piezoelectric materials that may be employed in various implementations include, by non-limiting example, quartz, sucrose, topaz, tourmaline, lead titanate, barium titanate, lead zirconate titanate, and any other crystal or material that exhibits piezoelectric properties.

For sonic energy sources that couple to a chuck, the sonic energy sources may be fastened to a lower surface of the chuck, embedded in the chuck, or fixedly attached to the side of the chuck opposite the side that contacts the substrate. Sonic energy sources embedded in the chuck may be used where the chuck rotates relative to the container/equipment to which the chuck is coupled. Also, multiple sonic energy sources may be coupled to the same chuck in various implementations to ensure the energy transmits evenly across the surface of the chuck.

For sonic energy sources coupled with a spindle (as in the sonic energy source 52 of FIG. 4), the sonic energy may transmitted using a sleeve and bearing coupled around the spindle in various implementations, or the sonic energy source may transmit the energy to the entire spindle assembly (including the motor). In other implementations, the sonic energy source may be coupled on an end of the spindle opposing the end coupled to the chuck 48 so that the energy can be transmitted up the shaft of the spindle. Multiple sonic energy sources could be connected to the spindle in some implementations.

In the various system implementations illustrated herein, the sonic energy sources may take various forms, depending upon which component of the system they are coupled to (substrate chuck, spindle, or water medium). A wide variety of frequencies may be employed by the sonic energy sources which may range from about 20 kHz to about 3 GHz. Where the sonic frequencies utilized by the sonic energy source 40 are above 360 kHz, the energy source may also be referred to as a megasonic energy source (as used herein, ultrasonic is used to refer to both ultrasonic and megasonic frequencies for the purposes of easier discussion). In particular implementations, the sonic energy source may generate ultrasonic vibrations at a frequency of 40 kHz at a power of 80 W. In various implementations, the sonic energy source may apply a frequency of between about 30 kHz to about 50 kHz or about 35 kHz to about 45 kHz. However, in various implementations, frequencies higher than 50 kHz may be employed, including megasonic frequencies. A wide variety of power levels may also be employed in various implementations.

In various system implementations (bath or liquid puddle implementations), the action of the sonic energy may be assisted by bias forces applied to the side of the substrate supported by the support tape. Several non-limiting examples of systems used to apply bias forces will now be discussed. However, while these systems are discussed separately, any combination of the systems/techniques could be used in various method and system implementations.

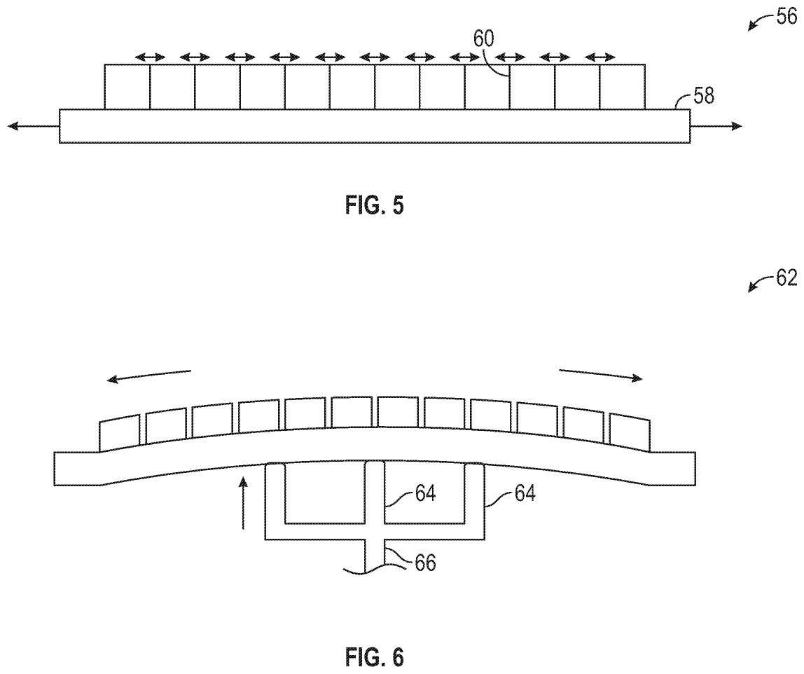

Referring to FIG. 5, an implementation of a semiconductor substrate 56 is illustrated following laser irradiation and during exposure to sonic energy using any of the methods disclosed here. The vertical lines 60 on the substrate represent the location of the street regions. As illustrated, the support tape 58 in this implementation is a stretching tape (or one capable of being stretched) and is currently being stretched away from the center of the substrate 56 as indicated by the outward facing arrows. The effect of the outward stretching is to correspondingly stress the damage layers in the streets of the substrate. When used in combination with exposure to sonic energy, the stretching causes cracks to form and/or propagate in the street regions across the thickness of the substrate, thus singulating the plurality of die. Where the stretching tape does not reversibly stretch, but remains at least partially stretched following application of the stretching force, the use of stretching to assist in singulating the plurality of die may also separate the edges of the plurality of die from each other as an aid for die picking/removal from the tape during subsequent processing. In implementations where stretchable tape is used, a frame may or may not be employed before the stretching operation is completed. In these implementations, the laser irradiation process of the streets may be conducted before the substrate is mounted to the tape.

In FIG. 6, a system for applying bias force at a plurality of point locations across the surface of a substrate 62 is illustrated. As illustrated, the substrate 62 has been mounted to tape (which may be any tape type disclosed in this document). While the substrate 62 is experiencing sonic energy using any method disclosed in this document, the side of the substrate 62 is then lifted upwardly at point locations from two or more lifting pins 64 coupled with a lifting mechanism 66. The two or more lifting pins 64 apply point bias forces on the surface of the substrate 62, which causes some stretching of the tape (reversible or irreversible in various implementations) and also imposes point stresses on particular streets in the substrate relative to other streets. The use of point stresses may assist with the initial formation/propagation of cracks within the damage areas of the streets and cause certain streets to singulate before others, causing the point stresses to then be transferred to the unsingulated streets, causing them to singulate sequentially. In various implementations, tape stretching may be conducted either at the same time or after the point bias forces are applied. In various implementations, the two or more lifting pins 64 may be the same length. In others, the two more lifting pins 64 may differ in lengths—some may be the same length, alternating pins may differ in length, all may differ in length, the center pin may be the longest and each pin may be shorter as a function of its radial distance from the center of the substrate, or any combination of the foregoing, or any other length arrangement desirable to create a desired force gradient across the substrate. In various implementations, frames may be employed where point bias forces are used; in others frames may be omitted or applied after the point bias force and die singulation and/or tape stretching has been completed.

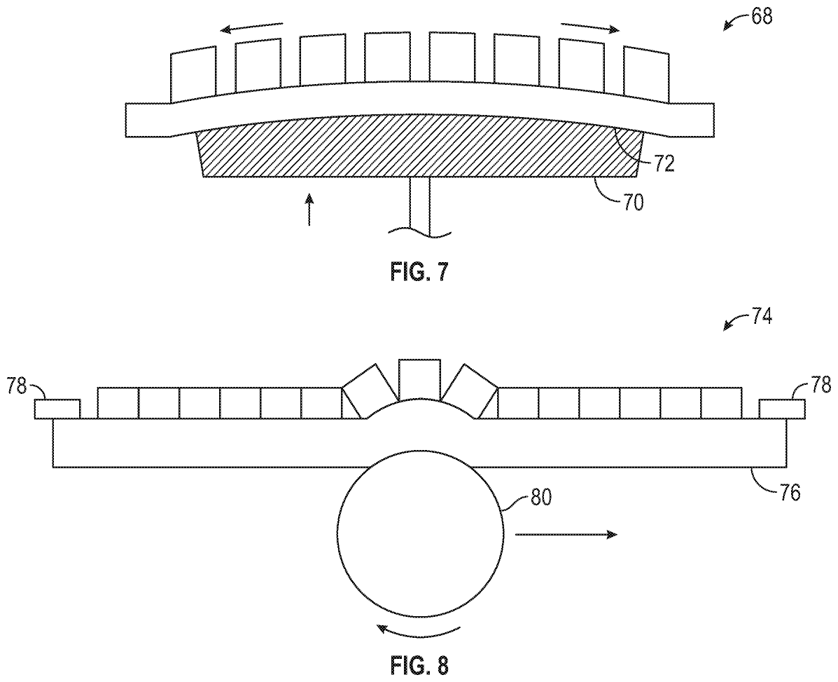

Referring to FIG. 7, an implementation of a system for applying continuous or semicontinuous bias force across a surface of a semiconductor substrate 68 is illustrated. As illustrated, after the semiconductor substrate 68 is mounted to support tape (which may be any tape type disclosed in this document), a chuck 70 with a curved (contoured) surface 72 is then brought up into contact using a lifting mechanism with the surface of the substrate 68 that faces the support tape while the substrate is experiencing sonic energy using any method disclosed herein. As illustrated, the curved surface 72 applies a continuous bias force across the surface of the substrate 68, causing the damage layer in each of the streets in the substrate to experience a bias force that is a function of the shape of the curved surface 72, thereby causing cracks to form/propagate across the thickness of the substrate 68 and singulating the plurality of die. A wide variety of curved surface designs may be utilized in various implementations to create the desired pressure gradient, vertical displacement, and/or moment about the street based on any of a variety of factors, including, by non-limiting example, die size, street dimensions, damage layer characteristics, mechanical strength parameters of the substrate, thickness of the substrate, and any other factor capable of affecting the singulation process. In some implementations, stretching of the tape may be conducted during the application of the bias force. In other implementations, a semicontinuous bias force may be applied to the surface of the wafer through use of a curved surface 72 with discontinuities therein such as, by non-limiting example, grooves, ringed grooves, raised projections, holes, radial lines, random patterns of raised features, and any other patterning of the curved surface 72. Following singulation of the plurality of die, the chuck 70 may then be lowered and the plurality of die picked or otherwise removed from the tape for subsequent packaging operations.

Referring to FIG. 8, a system for applying a moving localized bias force across a surface of a semiconductor substrate 74 is illustrated. As illustrated, the semiconductor substrate 74 has been mounted to tape 76 and frame 78 and is supported by the same. While being exposed to sonic energy using any method disclosed herein, a roller 80 is then contacted against the surface of the substrate 74 that faces the tape and then moves across the surface while rotating, applying a moving local bias force to the surface. As illustrated, the local bias force causes cracks to form/propagate in the streets closest to the roller, causing the plurality of die to separate. Where the roller is in the form of a long bar extending into and out of the plane of the paper of the drawing of FIG. 8, it may cause the sequential singulation of the streets in a direction substantially parallel with the longest length of the roller in various implementations. Since the streets in the substantially perpendicular direction may not singulate, the roller 80 may then be rotated about 90 degrees and then rolled across the surface of the semiconductor substrate again to singulate the remaining streets. In other implementations, however, the roller may take the form of substantially a sphere and may be applied to the surface of the substrate in any of a wide variety of patterns, including, by non-limiting example, radially, spirally, repeatedly in various different locations across the surface, in perpendicularly intersecting lines, and any of a wide variety of possible application patterns. In various implementations, the radius of the roller may be a function of, by non-limiting example, the die size, street size, substrate size, substrate thickness or any other parameter useful for ensuring singulation of the die without causing die damage due to die edge collision during the bias force application process. Any of a wide variety of roller designs may be constructed using the principles disclosed in this document. As previously discussed with the other bias force application systems and methods, tape stretching may also be employed during the bias force application process using a localized bias force.

In places where the description above refers to particular implementations of die singulation methods and systems and implementing components, sub-components, methods and sub-methods, it should be readily apparent that a number of modifications may be made without departing from the spirit thereof and that these implementations, implementing components, sub-components, methods and sub-methods may be applied to other die singulation methods and systems.

1. A method of singulating a plurality of die from a semiconductor substrate, the method comprising:
forming a damage layer beneath a surface of a die street, the die street connecting a plurality of semiconductor die, the plurality of semiconductor die formed on the semiconductor substrate;
mounting the semiconductor substrate to a support tape;
exposing the semiconductor substrate to sonic energy using a sonic energy source; and
singulating the plurality of die at the damage layer using the sonic energy.

2. The method of claim 1, wherein the sonic energy source emits sonic energy between 20 kHz to 3 GHz.

3. The method of claim 1, wherein forming the damage layer further comprises irradiating the die street with a laser beam at a focal point within the semiconductor substrate at one or more spaced apart locations beneath the surface of the die street to form the damage layer.

4. The method of claim 1, wherein forming the damage layer further comprises:
irradiating the die street with a laser beam at a focal point at a first depth within the semiconductor substrate at one or more spaced apart locations beneath the surface of the die street; and
irradiating the die street with a laser beam at a focal point at a second depth within the semiconductor substrate at one or more spaced apart locations beneath the surface of the die street.

5. The method of claim 1, wherein the semiconductor substrate is silicon carbide.

6. The method of claim 1, wherein singulating the plurality of die at the damage layer further comprises stretching the support tape while applying the sonic energy.

7. The method of claim 1, wherein singulating the plurality of die at the damage layer further comprises applying one of a continuous and semicontinuous bias force across a surface of the semiconductor substrate while applying the sonic energy.

8. The method of claim 1, wherein singulating the plurality of die at the damage layer further comprises applying a moving localized bias force across a surface of the semiconductor substrate while applying the sonic energy.

9. The method of claim 1, wherein singulating the plurality of die at the damage layer further comprises applying a plurality of point bias forces distributed across a surface of the semiconductor substrate while applying the sonic energy.

10. A method of singulating a plurality of die from a semiconductor substrate, the method comprising:
irradiating the die street with a laser beam at a focal point within the semiconductor substrate at one or more spaced apart locations beneath the surface of the die street to form a damage layer beneath a surface of a die street, the die street connecting a plurality of semiconductor die, the plurality of semiconductor die formed on the semiconductor substrate;
mounting the semiconductor substrate to a support tape;
exposing the semiconductor substrate to sonic energy using a sonic energy source; and
singulating the plurality of die at the damage layer using the sonic energy.

11. The method of claim 10, wherein the sonic energy source emits sonic energy between 20 kHz to 3 GHz.

12. The method of claim 10, wherein irradiating the die street with the laser beam further comprises irradiating the die street with the laser beam at the focal point at a first depth within the semiconductor substrate at the one or more spaced apart locations beneath the surface of the die street; and
irradiating the die street with the laser beam at a focal point at a second depth within the semiconductor substrate at one or more spaced apart locations beneath the surface of the die street.

13. The method of claim 10, wherein the semiconductor substrate is silicon carbide.

14. The method of claim 10, wherein singulating the plurality of die at the damage layer further comprises stretching the support tape while applying the sonic energy.

15. The method of claim 10, wherein singulating the plurality of die at the damage layer further comprises applying one of a continuous and semicontinuous bias force across a surface of the semiconductor substrate while applying the sonic energy.

16. The method of claim 10, wherein singulating the plurality of die at the damage layer further comprises applying a moving localized bias force across a surface of the semiconductor substrate while applying the sonic energy.

17. The method of claim 10, wherein singulating the plurality of die at the damage layer further comprises applying a plurality of point bias forces distributed across a surface of the semiconductor substrate while applying the sonic energy.

18. A method of singulating a plurality of die from a silicon carbide substrate, the method comprising:
irradiating the die street with a laser beam at a focal point within the silicon carbide substrate at one or more spaced apart locations beneath the surface of the die street to form a damage layer beneath a surface of a die street, the die street connecting a plurality of semiconductor die, the plurality of semiconductor die formed on the silicon carbide semiconductor substrate;
mounting the silicon carbide substrate to a support tape; and
singulating the plurality of die at the damage layer using sonic energy from a sonic energy source.

19. The method of claim 18, wherein singulating the plurality of die at the damage layer further comprises stretching the support tape while applying the sonic energy.

20. The method of claim 18, wherein singulating the plurality of die at the damage layer further comprises applying one of a continuous and semicontinuous bias force across a surface of the semiconductor substrate while applying the sonic energy.
